(19) United States
(12) Patent Application Publication
(10) Pub. No.: US 2024/0178254 A1
(43) Pub. Date: May 30, 2024

(54) LIGHT-RECEIVING ELEMENT AND ELECTRONIC APPARATUS

(71) Applicant: SONY SEMICONDUCTOR SOLUTIONS CORPORATION, KANAGAWA (JP)

(72) Inventor: KEIICHI NAKAZAWA, KANAGAWA (JP)

(21) Appl. No.: 18/551,643

(22) PCT Filed: Jan. 27, 2022
(86) PCT No.: PCT/JP2022/003005

§ 371 Date: Sep. 21, 2023

(30) Foreign Application Priority Data
Mar. 31, 2021 (JP) 2021-062419

(51) Int. Cl. H01L 27/146

(52) U.S. Cl. CPC H01L 27/1463; H01L 27/14607; H01L 27/14627; H01L 27/14645

(57) ABSTRACT

Provided is a light-receiving element capable of reducing a decrease in a photodiode region of a pixel. The light-receiving element includes a pixel array unit in which a plurality of pixels is disposed in an array, the pixels being capable of generating an electrical signal according to light incident from outside. Each of the plurality of pixels includes a photoelectric conversion region of a first conductivity type, the photoelectric conversion region photoelectrically converting the light incident, an inter-pixel separation part that defines an outer edge shape of the pixels, and insulates and separates adjacent pixels, and a pinning region of a second conductivity type, the pinning region being formed between the photoelectric conversion region and a sidewall of the inter-pixel separation part. The plurality of pixels is disposed in an array so as to form a honeycomb structure in which corner parts where a plurality of sides intersects are obtuse angles in plan view.

### TECHNICAL FIELD

The present disclosure relates to a light-receiving element and an electronic apparatus including the light-receiving element.

### BACKGROUND ART

A CMOS image sensor (CIS), which is an imaging element, tends to increase the number of pixels per unit area (pixel density) with a technique of densifying and miniaturizing a semiconductor element in order to acquire a high-resolution image. As one of techniques for achieving the miniaturization, there is used a technique for increasing saturation capacitance of a photodiode by completely separating pixels by a trench, even if a size per pixel decreases. The CIS includes a pixel array in which photodiodes that constitute each pixel are disposed in an array.

In general, a pixel array includes pixels disposed vertically and horizontally, the pixels having a rectangular shape in plan view. Meanwhile, as disclosed in Patent Document 1, a pixel array in which hexagonal pixels are disposed is also proposed.

### CITATION LIST

### Patent Document

Patent Document 1: Japanese Patent Application Laid-Open No. 2006-29839

### SUMMARY OF THE INVENTION

### Problems to be Solved by the Invention

Incidentally, even in a method in which pixels are completely separated by a trench, a side surface of the trench is need to be pinned, and therefore, the side surface of the trench needs to be a p-type. Meanwhile, because the pixels have a square shape, corner portions thereof are right angles, and when a p-type semiconductor region is formed from a separation portion, boron penetration and electric field are applied roundly at a corner portion. Photodiode regions are small especially in miniaturized pixels due to the boron penetration and the electric field being applied roundly. Patent Document 1 discloses hexagonal pixels, but does not consider formation of a sufficient photodiode region.

The present disclosure has been made in view of such circumstances, and an object of the present disclosure is to provide a light-receiving element and electronic apparatus capable of reducing a decrease in a photodiode region of a pixel.

### Solutions to Problems

An aspect of the present disclosure is a light-receiving element including a pixel array unit in which a plurality of pixels is disposed in an array, the pixels being capable of generating an electrical signal according to light incident from outside, in which each of the plurality of pixels includes a photoelectric conversion region of a first conductivity type, the photoelectric conversion region photoelectrically converting the light incident, an inter-pixel separation part that defines an outer edge shape of the pixels, and insulates and separates adjacent the pixels, and a pinning region of a second conductivity type that is opposite to the first conductivity type, the pinning region being formed between the photoelectric conversion region and a sidewall of the inter-pixel separation part, and the plurality of pixels is disposed in an array so as to form a honeycomb structure in which corner parts where a plurality of sides intersects are obtuse angles in plan view.

Another aspect of the present disclosure is an electronic apparatus including a light-receiving element including a pixel array unit in which a plurality of pixels is disposed in an array, the pixels being capable of generating an electrical signal according to light incident from outside, in which each of the plurality of pixels includes a photoelectric conversion region of a first conductivity type, the photoelectric conversion region photoelectrically converting the light incident, an inter-pixel separation part that defines an outer edge shape of the pixels, and insulates and separates adjacent the pixels, and a pinning region of a second conductivity type that is opposite to the first conductivity type, the pinning region being formed between the photoelectric conversion region and a sidewall of the inter-pixel separation part, and the plurality of pixels is disposed in an array so as to form a honeycomb structure in which corner parts where a plurality of sides intersects are obtuse angles in plan view.

### BRIEF DESCRIPTION OF DRAWINGS

FIG. 1 is a schematic configuration diagram illustrating an entire solid-state imaging device according to a first embodiment of the present technology.

FIG. 2 is a diagram illustrating an equivalent circuit of a pixel according to the first embodiment.

FIG. 3 is a cross-sectional view of a pixel taken, in a vertical direction, along an alternate long and short dash line A-A′ on the pixel in FIG. 1.

FIG. 4 is a plan view of an example of a pixel array unit according to a comparative example of the first embodiment.

FIG. 5 is a plan view of an example of arrangement of pixels in a pixel array unit according to the first embodiment.

FIG. 6 is a diagram illustrating an example of a case where the first embodiment is compared with the comparative example.

FIG. 7 is a diagram illustrating a process flow (1) for forming a pixel according to the first embodiment.

FIG. 8 is a diagram illustrating a process flow (2) for forming the pixel according to the first embodiment.

FIG. 9 is a diagram illustrating a process flow (3) for forming the pixel according to the first embodiment.

FIG. 10 is a diagram illustrating a process flow (4) for forming the pixel according to the first embodiment.

FIG. 11 is a plan view illustrating an example in which an on-chip lens is disposed for each pixel according to a comparative example of a modification of the first embodiment.

FIG. 12 is a plan view illustrating an example in which an on-chip lens is disposed for each pixel according to the modification of the first embodiment.

FIG. 13 is a plan view illustrating an example of pixels arranged in a pixel array unit in a solid-state imaging device according to a second embodiment of the present technology.

FIG. 14 is a cross-sectional view of the pixel taken, in a vertical direction, along the alternate long and short dash line A-A′ in FIG. 1, according to the second embodiment.

FIG. 15 is a plan view illustrating an example of pixels arranged in a pixel array unit in a modification of the second embodiment.

FIG. 16 is a plan view illustrating an example of pixels arranged in a pixel array unit in a solid-state imaging device according to a third embodiment of the present technology.

FIG. 17 is a cross-sectional view of the pixel taken, in a vertical direction, along the alternate long and short dash line A-A′ in FIG. 1, according to the third embodiment.

FIG. 18 is a plan view illustrating an example of pixels arranged in a pixel array unit in a first modification of the third embodiment.

FIG. 19 is a plan view illustrating an example of pixels arranged in a pixel array unit in a second modification of the third embodiment.

FIG. 20 is a plan view illustrating an example of pixels arranged in a pixel array unit in a third modification of the third embodiment.

FIG. 21 is a block diagram illustrating a configuration example of an embodiment of an imaging device as an electronic apparatus to which the present technology is applied.

### MODES FOR CARRYING OUT THE INVENTION

Hereinafter, embodiments of the present disclosure will be described with reference to the drawings. In the description of the drawings referred to in the following description, the same or similar parts are denoted by the same or similar reference signs, and duplicated description is omitted. However, it should be noted that the drawings are schematic, and the relationship between the thickness and the plane dimension, the ratio of the thickness of each device and each member, and the like are different from actual ones. Therefore, specific thicknesses and dimensions should be determined in consideration of the following description. Furthermore, it goes without saying that dimensional relationships and ratios are partly different among the drawings.

In this specification, a “first conductivity type” means one of a p-type and an n-type, and a “second conductivity type” means one of the p-type and the n-type different from the “first conductivity type”. Furthermore, “n” or “p” to which “+” or “−” is added means a semiconductor region having a relatively higher or lower impurity density than that of a semiconductor region to which “+” or “−” is not added. However, even in the semiconductor regions to which the same “n” and “n” are added, it does not mean that the impurity densities of the semiconductor regions are exactly the same.

Furthermore, definitions of directions such as up and down in the following description are merely definitions for convenience of description, and do not limit the technical idea of the present disclosure. For example, it goes without saying that if a target is observed while being rotated by 90°, the upward and downward directions are converted into rightward and leftward directions, and if the target is observed while being rotated by 180°, the upward and downward directions are inverted.

Note that the effects described in the present specification are merely examples and are not limited, and other effects may be provided.

### First Embodiment

In the present disclosure, there will be described an array-type light-receiving element including pixels each having an outer edge shape in a regular hexagonal shape in plan view (or in a plane parallel to opening surfaces (main surface) of the pixels). In particular, in the present embodiment, examples in which each pixel has an outer edge shape in a regular hexagonal shape will be described. Note that, in the present disclosure, the “outer edge shape” refers to a geometric shape of an outer edge of an object in plan view, and the term “plan view” may be omitted when context clearly indicates the outer edge.

### (Overall Configuration of Solid-State Imaging Device)

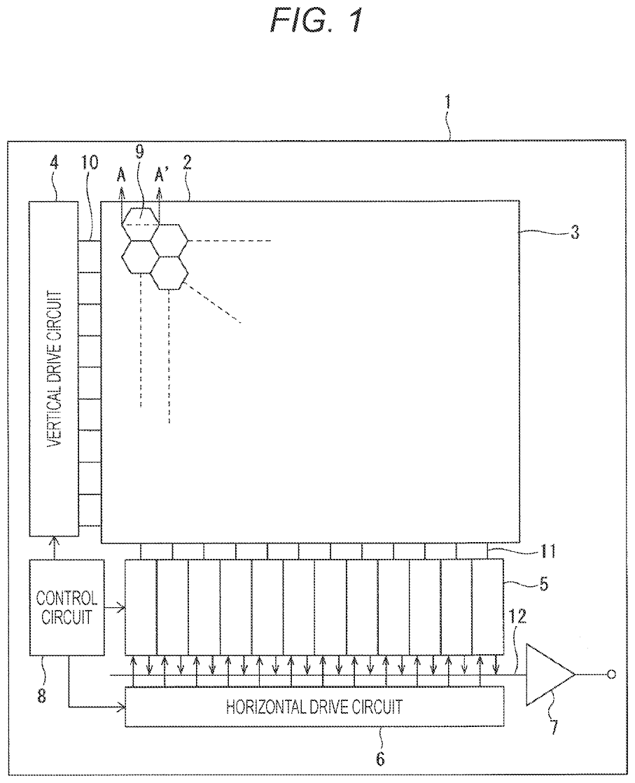

A solid-state imaging device 1 as a light-receiving element according to a first embodiment of the present technology will be described. FIG. 1 is a schematic configuration diagram illustrating an entire solid-state imaging device 1 according to a first embodiment of the present technology.

The solid-state imaging device 1 in FIG. 1 is a back-illuminated complementary metal oxide semiconductor (CMOS) image sensor. The solid-state imaging device 1 takes in image light from a subject via an optical lens, converts an amount of incident light formed on an imaging surface into an electrical signal on a pixel-by-pixel basis, and outputs the electrical signal as a pixel signal.

As illustrated in FIG. 1, the solid-state imaging device 1 according to the first embodiment includes a substrate 2, a pixel array unit 3, a vertical drive circuit 4, column signal processing circuits 5, a horizontal drive circuit 6, an output circuit 7, and a control circuit 8.

The pixel array unit 3 has a plurality of pixels 9 regularly arranged in a two-dimensional array on the substrate 2. The respective pixels 9 in the pixel array unit 3 have a regular hexagonal shape in plan view, and are disposed in an array so as to form a honeycomb structure.

The vertical drive circuit 4 includes, for example, a shift register, selects a desired pixel drive wiring line 10, supplies a pulse for driving the pixels 9 to the selected pixel drive wiring line 10, and drives each pixel 9 on a row basis. That is, the vertical drive circuit 4 selectively scans the respective pixels 9 in the pixel array unit 3 sequentially in a vertical direction on a row basis, and supplies pixel signals based on signal charges generated in accordance with an amount of received light in photoelectric conversion units of the respective pixels 9, to the column signal processing circuits 5 through vertical signal lines 11.

A column signal processing circuit 5 is disposed, for example, for each column of the pixels 9, and performs signal processing such as noise removal on signals outputted from the pixels 9 of one line for each pixel column. For example, the column signal processing circuit 5 performs signal processing such as correlated double sampling (CDS) for removing a pixel-specific fixed pattern noise, and analog digital (AD) conversion.

The horizontal drive circuit 6 includes, for example, a shift register, sequentially outputs horizontal scanning pulses to the column signal processing circuits 5, sequentially selects each of the column signal processing circuits 5, and causes each of the column signal processing circuits 5 to output a pixel signal having been subjected to signal processing, to a horizontal signal line 12.

The output circuit 7 performs signal processing on the pixel signals sequentially supplied from each of the column signal processing circuits 5 through the horizontal signal line 12, and outputs the pixel signals. As the signal processing, for example, buffering, black level adjustment, column variation correction, various kinds of digital signal processing, and the like can be used.

The control circuit 8 generates, on the basis of a vertical synchronization signal, a horizontal synchronization signal, and a master clock signal, a clock signal or a control signal in accordance with which the vertical drive circuit 4, the column signal processing circuits 5, the horizontal drive circuit 6, and the like operate. Then, the control circuit 8 outputs the clock signal or control signal thus generated to the vertical drive circuit 4, the column signal processing circuits 5, the horizontal drive circuit 6, and the like.

### (Equivalent Circuit of Pixel)

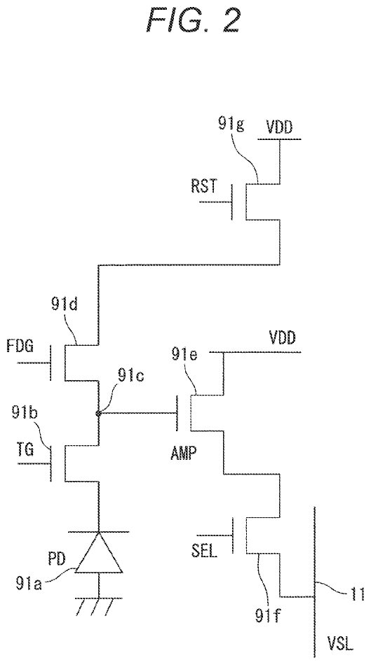

FIG. 2 illustrates an equivalent circuit of a pixel 9.

The pixel 9 includes a photodiode (PD) 91a, a transfer transistor (TG) 91b, a floating diffusion (FD) unit 91c, a conversion-efficiency adjustment transistor (FDG) 91d, an amplification transistor (AMP) 91e, a selection transistor (SEL) 91f, and a reset transistor (RST) 91g. The transfer transistor 91b, the conversion-efficiency adjustment transistor 91d, the amplification transistor 91e, the selection transistor 91f, and the reset transistor 91g are constituted by, for example, a MOS transistor.

The photodiode 91a forms a photoelectric conversion unit that photoelectrically converts incident light. An anode of the photodiode 91a is grounded. A cathode of the photodiode 91a is connected to a source of the transfer transistor 91b.

A drain of the transfer transistor 91b is connected to the FD unit 91c. The transfer transistor 91b transfers signal charge from the photodiode 91a to the FD unit 91c in response to a transfer signal applied to a gate.

The FD unit 91c stores therein the signal charge transferred from the photodiode 91a via the transfer transistor 91b. The potential of the FD unit 91c is modulated in accordance with an amount of the signal charge stored in the FD unit 91c.

The FD unit 91c is connected to a source of the conversion-efficiency adjustment transistor 91d. A drain of the conversion-efficiency adjustment transistor 91d is connected to a source of the reset transistor 91g. The conversion-efficiency adjustment transistor 91d adjusts conversion efficiency of signal charge in response to a conversion-efficiency adjustment signal applied to the gate.

The FD unit 91c is connected to a gate of the amplification transistor 91e. A source of the selection transistor 91f is connected to a drain of the amplification transistor 91e. A source of the amplification transistor 91e is applied with a power supply potential (VDD). The amplification transistor 91e amplifies potential of the FD unit 91c.

The drain of the reset transistor 91g is applied with the power supply potential (VDD). The reset transistor 91g initializes (resets) the signal charge stored in the FD unit 91c, in response to a reset signal applied to the gate.

A drain of the selection transistor 91f is connected to the vertical signal line 11. The selection transistor 91f selects a pixel 9 in response to a selection signal applied to a gate. In a case where the pixel 9 is selected, a pixel signal corresponding to the potential amplified by the amplification transistor 91e is output through the vertical signal line 11.

### <Cross-Sectional Configuration of Pixel>

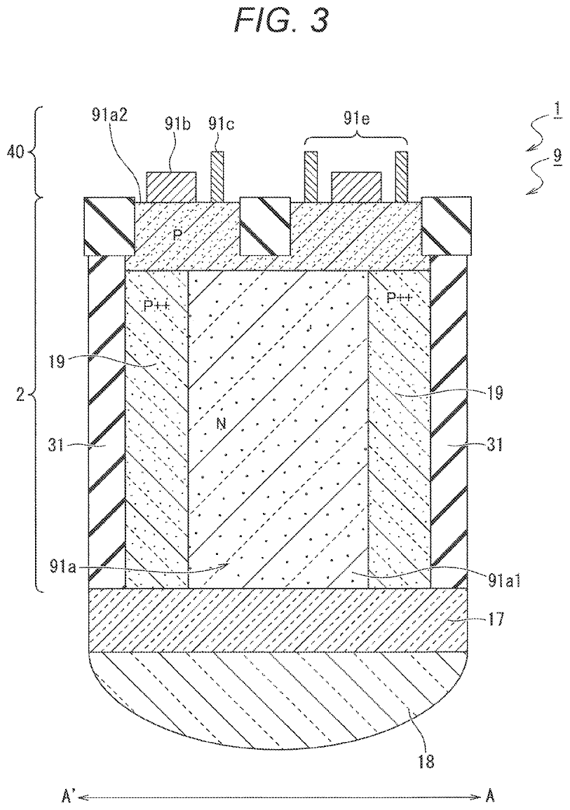

FIG. 3 illustrates a cross-sectional view of the pixel 9, which is taken, in a vertical direction, along an alternate long and short dash line A-A′ on the pixel 9 in FIG. 1.

Hereinafter, a surface on a light incident surface side (lower side in FIG. 3) of each member of the solid-state imaging device 1 is referred to as a “back surface”, and a surface on a side (upper side in FIG. 3) opposite to the light incident surface side of each member of the solid-state imaging device 1 is referred to as a “front surface”.

As illustrated in FIG. 3, a color filter 17 and an on-chip lens 18 are stacked in this order on a back surface side of the substrate 2. Moreover, a wiring layer 40 is stacked on a front surface of the substrate 2.

The photodiode 91a is formed on the substrate 2 of the solid-state imaging device 1. As the substrate 2, for example, a semiconductor substrate including silicon (Si) can be used. The photodiode 91a includes an n-type semiconductor region 91a1, and a p-type semiconductor region 91a2 formed on a front surface side of the substrate 2. In the photodiode 91a, a signal charge corresponding to an amount of incident light is generated, and the generated signal charge is stored in the n-type semiconductor region 91a1.

Furthermore, each pixel 9 is electrically separated by an inter-pixel separation part 31. As illustrated in FIG. 3, the inter-pixel separation part 31 is formed in a depth direction from the back surface side of the substrate 2. Furthermore, the inter-pixel separation part 31 is formed in a lattice shape so as to surround each pixel 9, which will be described later. Moreover, insulation film for enhancing light shielding performance is embedded in the inter-pixel separation part 31.

A pinning region 19 to be a p-type semiconductor region in which boron is injected is formed between a sidewall of the inter-pixel separation part 31 and the n-type semiconductor region 91a1. Electrons that cause dark current are absorbed by holes that are majority carriers in the pinning region 19, by which dark current is reduced.

The on-chip lens 18 condenses irradiation light and causes the condensed light to be efficiently incident on the photodiode 91a in the substrate 2 via the color filter 17. The on-chip lens 18 can include an insulation material having no light absorption characteristics. Examples of the insulation material having no light absorption characteristics include silicon oxide, silicon nitride, silicon oxynitride, organic SOG, polyimide resin, fluorine resin, and the like.

The color filter 17 transmits a wavelength of light desired to be received by each pixel 9, and causes the transmitted light to be incident on the photodiode 91a in the substrate 2.

The wiring layer 40 is formed on the front surface side of the substrate 2 and includes the transfer transistor 91b as a pixel transistor, the floating diffusion unit 91c, the conversion-efficiency adjustment transistor 91d, the amplification transistor 91e, the selection transistor 91f, the reset transistor 91g, and wiring lines. Note that, in the example in FIG. 3, the transfer transistor 91b, the floating diffusion unit 91c, and the amplification transistor 91e are illustrated as representatives.

In the solid-state imaging device 1 having the above-described configuration, light is emitted from the back surface side of the substrate 2, transmitted through the on-chip lens 18 and the color filter 17, and is subjected to photoelectric conversion by the photodiode 91a, by which signal charge is generated. Then, the generated signal charge is output as a pixel signal by a vertical signal line 11, as illustrated in FIG. 1, via a pixel transistor formed in the wiring layer 40.

### Comparative Example of Embodiment

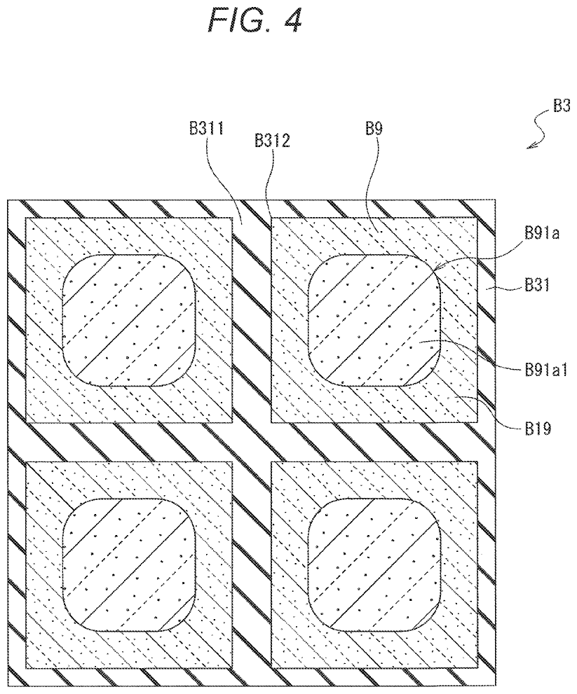

FIG. 4 is a plan view illustrating an example of a pixel array unit B3 according to a comparative example. As illustrated in FIG. 4, a plurality of pixels B9 is arranged at equal pitches in a row direction and column direction. The plurality of pixels B9 is electrically separated from one another by an inter-pixel separation part B31. The inter-pixel separation part B31 is formed in a lattice shape so as to surround each pixel B9.

In the pixel B9, an n-type semiconductor region B91a1 of a photodiode B91a is formed at the center position. A pinning region B19 to be a p-type semiconductor region is formed between the inter-pixel separation part B31 and the n-type semiconductor region B91a1.

In the comparative example, because the pixels B9 have a square shape, a corner part B312 where sides B311 of the inter-pixel separation part B31 intersect is a right angle, and when the pinning region B19 is formed from the inter-pixel separation part B31, boron penetration and electric field are applied roundly at the corner part B312. Therefore, the n-type semiconductor region B91a1 of the photodiode B91a is reduced in size.

### Measures According to First Embodiment

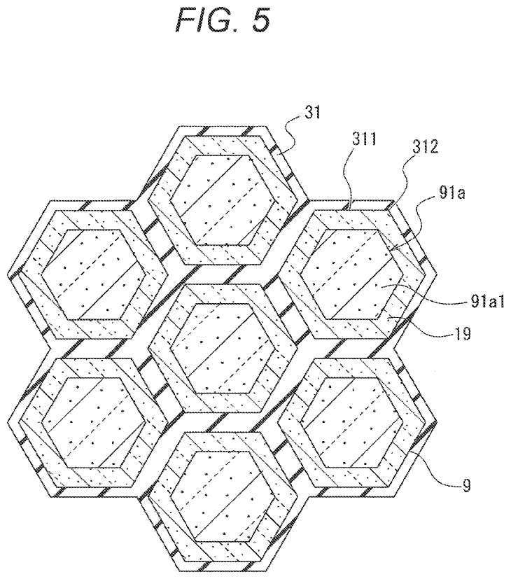

In the first embodiment of the present technology, as illustrated in FIG. 5, an outer edge shape of the pixel 9 is a regular hexagonal shape such that a corner part 312 where sides 311 of the inter-pixel separation part 31 intersect is an obtuse angle (90 degrees or more). The inter-pixel separation part 31 is formed in a lattice shape so as to surround each pixel 9 having a regular hexagonal shape.

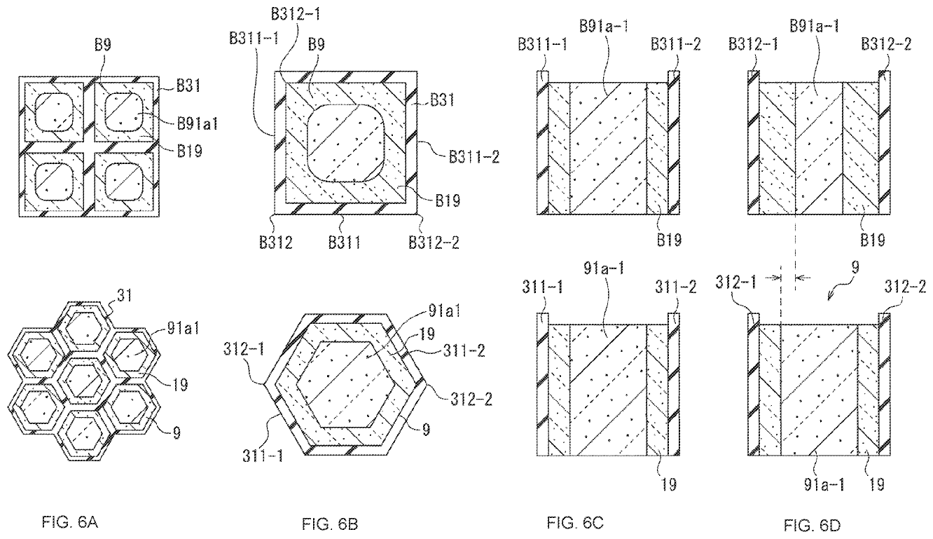

FIG. 6 is a diagram illustrating an example of a case where the first embodiment is compared with the comparative example. FIG. 6(a) illustrates a state where a plurality of pixels B9 according to the comparative example is arranged and a state where a plurality of pixels 9 according to the first embodiment is arranged.

As illustrated in FIG. 6(b), an outer edge shape of one pixel B9 is a square shape, and includes four sides B311 and four corner parts B312 where the four sides B311 intersect with one another. Meanwhile, as illustrated in FIG. 6(b), an outer edge shape of one pixel 9 is a regular hexagonal shape, and includes six sides 311 and six corner parts 312 where the six sides 311 intersect with one another.

FIG. 6(c) illustrates a cross section between a side B311-1 and side B311-2 of the pixel B9 according to the comparative example, and a cross section between a side 311-1 and side 311-2 of the pixel 9 according to the first embodiment. In FIG. 6(c), the n-type semiconductor region B91a1 in the comparative example is substantially equal to the n-type semiconductor region 91a1 in the first embodiment.

FIG. 6(d) illustrates a cross section between a corner part B312-1 and corner part B312-2 of the pixel B9 according to the comparative example, and a cross section between a corner part 312-1 and corner part 312-2 of the pixel 9 according to the first embodiment. In FIG. 6(d), the n-type semiconductor region B91a1 in the comparative example and the n-type semiconductor region 91a1 in the first embodiment are larger in area than the n-type semiconductor region B91a1 in the comparative example.

Therefore, by forming the outer edge shape of the pixel 9 into a regular hexagonal shape, overlapping of the p-type semiconductor region at a corner part 312 can be reduced in area, and a decrease in the n-type semiconductor region 91a1 can be reduced.

### [Method for Manufacturing Pixel]

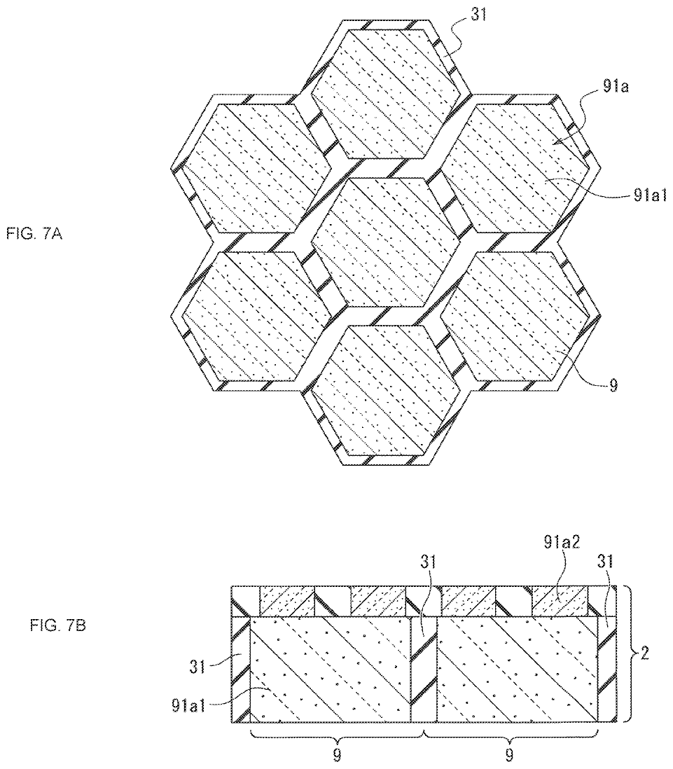

FIGS. 7 to 10 illustrate a process flow for forming the pixel 9 according to the first embodiment.

As illustrated in FIG. 7(a), the inter-pixel separation part 31 is formed along the outer edge shape of the pixel 9. In this case, as illustrated in FIG. 7(b), a groove part is formed between adjacent pixels 9 in the depth direction from the back surface side of the substrate 2, and an insulation film is embedded in the groove part to form the inter-pixel separation part 31.

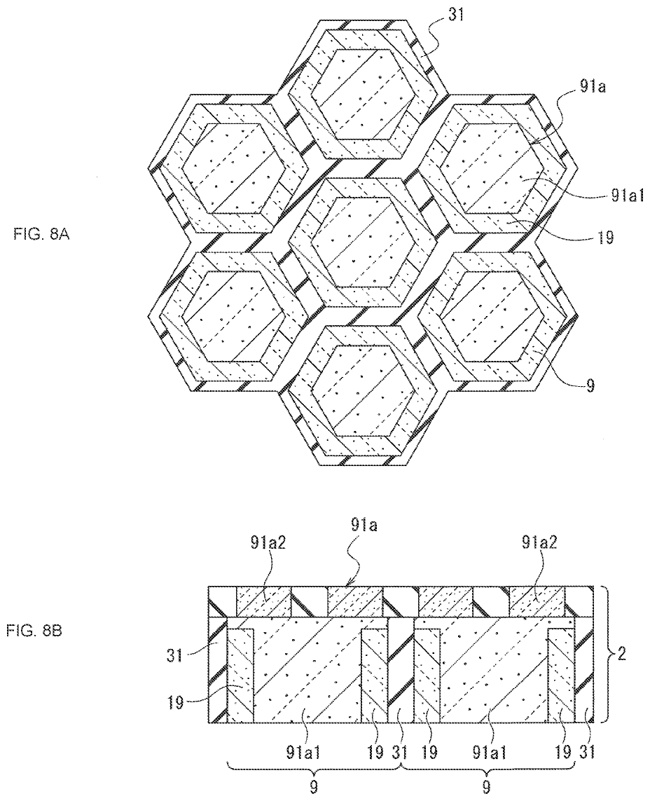

Next, as illustrated in FIG. 8(a), boron is injected into the sidewall of the inter-pixel separation part 31 to form the pinning region 19. As illustrated in FIG. 8(b), the pinning region 19 is formed in the depth direction from the back surface side of the substrate 2.

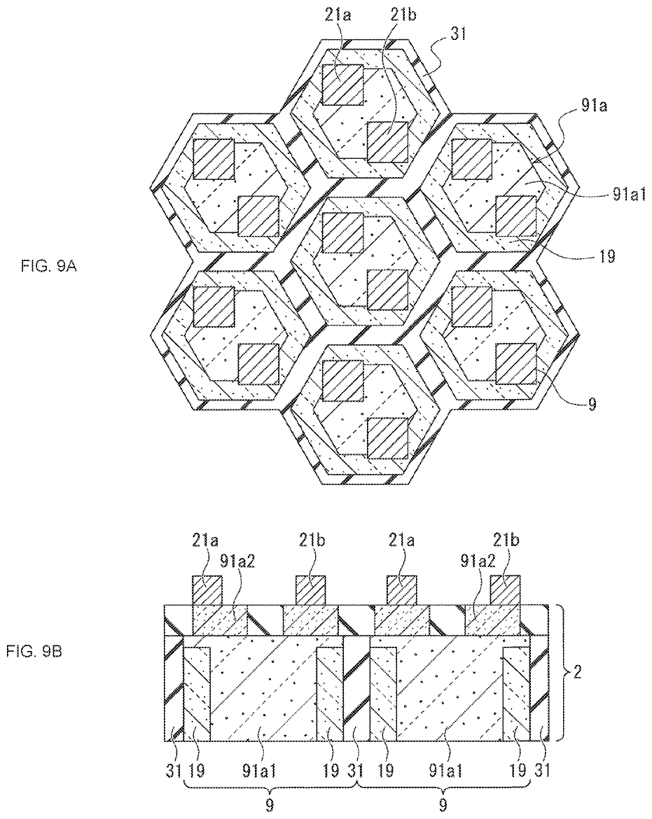

Next, as illustrated in FIG. 9(a), gate electrodes 21a and 21b are formed in each pixel 9. The gate electrodes 21a and 21b are formed on the front surface of the substrate 2 as illustrated in FIG. 9(b).

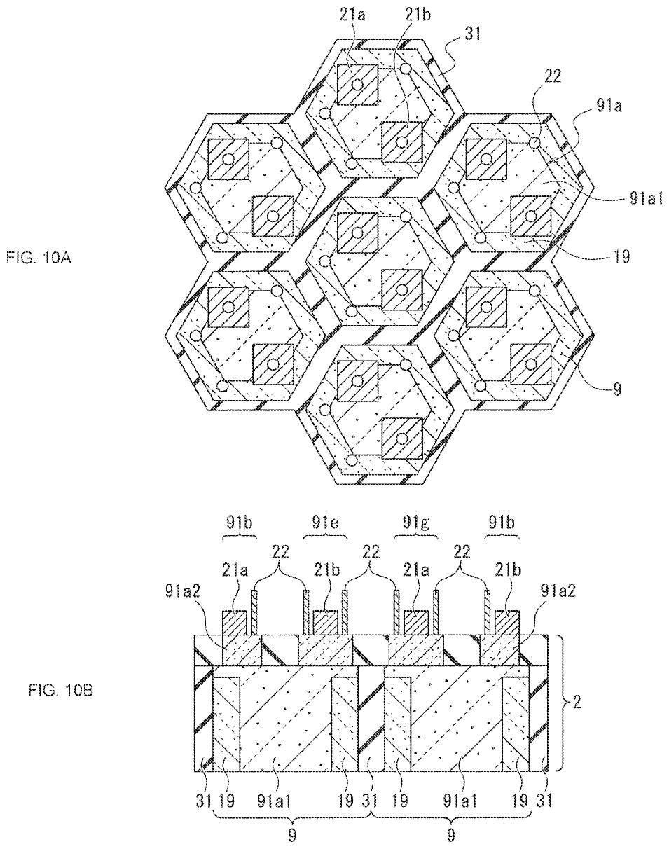

Next, as illustrated in FIG. 10(a), a contact 22 including a wiring line is formed in each pixel 9. In an example in FIG. 10(a), it is assumed that the conversion-efficiency adjustment transistor 91d, the amplification transistor 91e, the selection transistor 91f, and the reset transistor 91g are shared by four pixels 9 of two rows and two columns. Furthermore, a contact 22 is also formed on upper surfaces of the gate electrodes 21a and 21b.

As illustrated in FIG. 10(b), the contacts 22 are formed on the front surface of the substrate 2. The transfer transistor 91b, the amplification transistor 91e, and the reset transistor 91g are formed by the gate electrodes 21a and 21b, and the contacts 22. Furthermore, an FD unit 91c is formed by the contacts 22 between the transfer transistor 91b and the amplification transistor 91e. Moreover, an FD unit 91c is formed by the contacts 22 between the transfer transistor 91b and the reset transistor 91g.

### Effects of First Embodiment

As described above, because, according to the first embodiment, the outer edge shape of the pixel 9 is a regular hexagonal shape, the pixel array unit 3 can have a honeycomb structure, thereby increasing density of the pixels 9 per unit area and efficiently condensing light. Furthermore, by forming the outer edge shape of the pixel 9 into a regular hexagonal shape, corner parts 312 formed by the adjacent sides 311 have an obtuse angle, whereby a decrease in the n-type semiconductor region 91a1 of the photodiode 91a can be reduced. Because the decrease in the n-type semiconductor region 91a1 can be reduced, a signal charge amount (Qs) can be expected to be improved particularly in the pixels 9, which are miniaturized.

### Modification of First Embodiment

In a modification of the first embodiment, disposition of the above-described on-chip lens 18 will be described.

### Comparative Example of Modification of First Embodiment

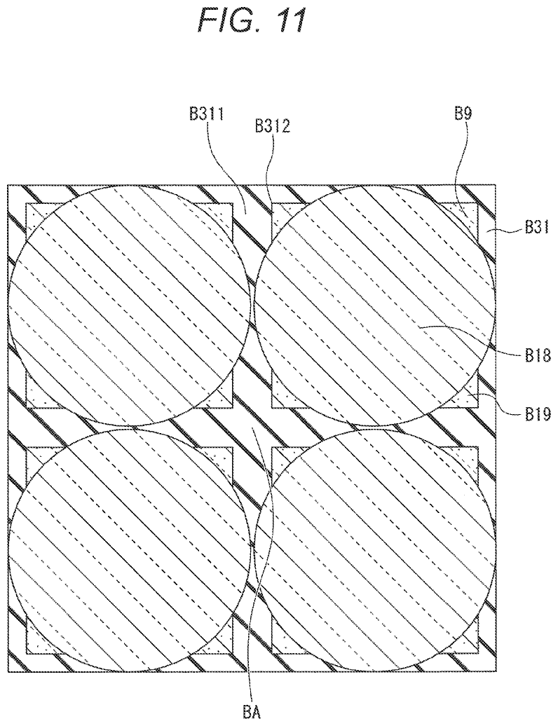

FIG. 11 is a plan view illustrating an example in which an on-chip lens B18 is disposed for each pixel B9 according to the comparative example. Note that, in FIG. 11, the same components as those in FIG. 4 described above are denoted by the same reference signs, and detailed description thereof will be omitted.

As illustrated in FIG. 11, a plurality of pixels B9 is arranged at equal pitches in a row direction and column direction. When the on-chip lens B18 is disposed for each pixel 9, a region between adjacent on-chip lenses B18 becomes an invalid region BA that is optically invalid.

### Effects of Modification of First Embodiment

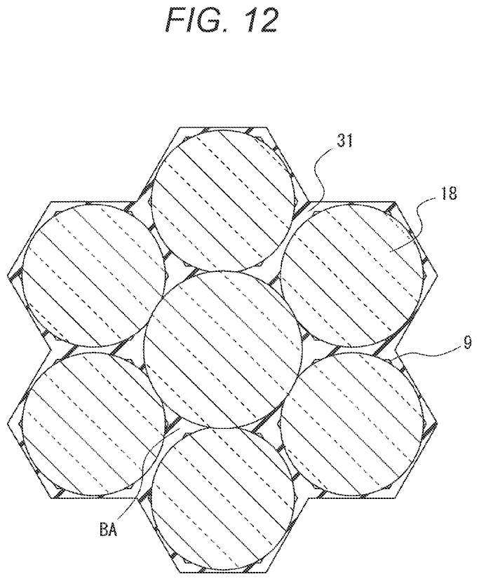

In a modification of the first embodiment, the outer edge shape of the pixel 9 is a regular hexagonal shape, and the pixels 9 are arranged to form a honeycomb structure, by which the invalid region BA of the on-chip lenses 18 as illustrated in FIG. 12 can be reduced.

### Second Embodiment

A second embodiment will describe a case where a pixel 9A has a dual pixel structure in which an n-type semiconductor region 91a1 and p-type semiconductor region 91a2 of a photodiode 91a are separated into two by an in-pixel separation part.

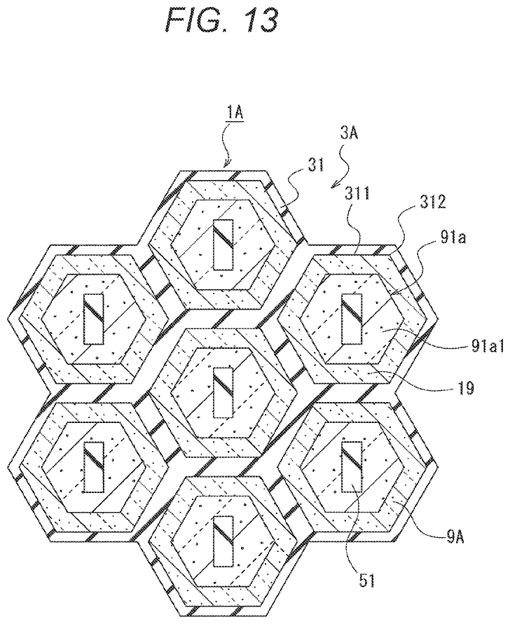

FIG. 13 is a plan view illustrating an example of pixels 9A arranged in a pixel array unit 3A in a solid-state imaging device 1A according to the second embodiment. Note that, in FIG. 13, the same components as those in FIG. 5 described above are denoted by the same reference signs, and detailed description thereof will be omitted.

In a pixel 9A, a trench (FFTI) 51 is formed as an in-pixel separation part. The trench 51 includes a metal film or an oxide film. The trench 51 is positioned at the center of the pixel 9A and is formed from the center of the pixel 9A toward a side 311 of an inter-pixel separation part 31.

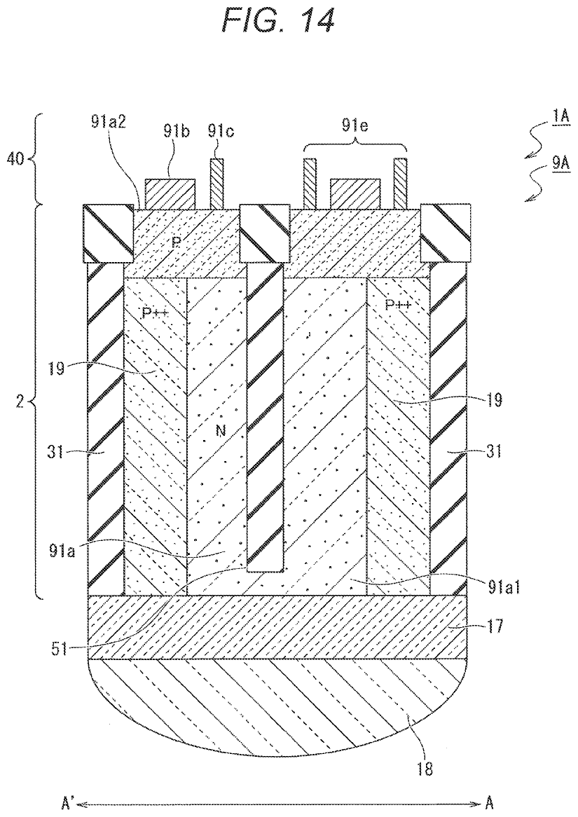

FIG. 14 illustrates a cross-sectional view of the pixel 9A taken, in a vertical direction, along the alternate long and short dash line A-A′ in FIG. 1. Note that, in FIG. 14, the same components as those in FIG. 3 described above are denoted by the same reference signs, and detailed description thereof will be omitted.

The trench 51 is formed from a front surface to a back surface side of a substrate 2 of the pixel 9A.

### Effects of Second Embodiment

As described above, according to the second embodiment, effects similar to those of the above-described first embodiment can be obtained, and even if same-color separation is performed by the trench 51, a decrease in the n-type semiconductor region 91a1 of the photodiode 91a can be reduced.

### Modification of Second Embodiment

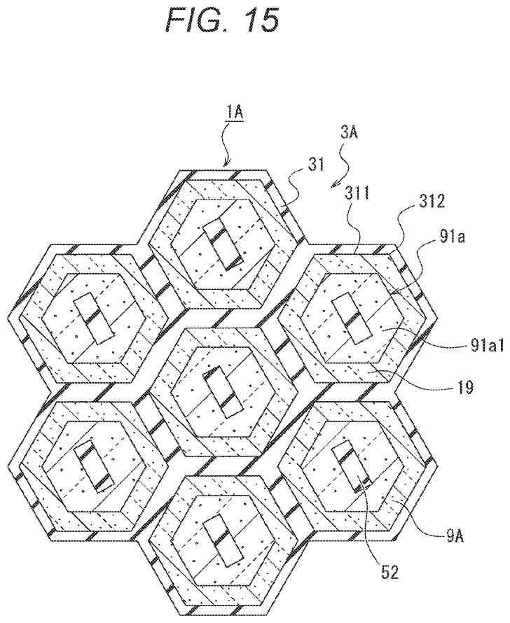

FIG. 15 is a plan view illustrating an example of pixels 9A arranged in a pixel array unit 3A in a modification of the second embodiment. Note that, in FIG. 15, the same components as those in FIG. 13 described above are denoted by the same reference signs, and detailed description thereof will be omitted.

In the pixel 9A, a trench (FFTI) 52 is formed. The trench 52 includes a metal film or an oxide film. The trench 52 is positioned at the center of the pixel 9A and is formed from the center of the pixel 9A toward a corner part 312 of the inter-pixel separation part 31.

### Third Embodiment

A third embodiment will describe a case where a pixel 9B has a dual pixel structure in which an n-type semiconductor region 91a1 and p-type semiconductor region 91a2 of a photodiode 91a are separated into two by an in-pixel separation part.

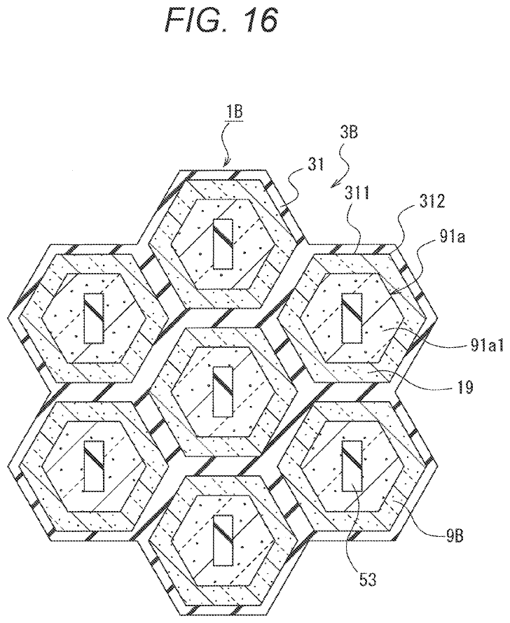

FIG. 16 is a plan view illustrating an example of pixels 9B arranged in a pixel array unit 3B in a solid-state imaging device 1B according to the third embodiment. Note that, in FIG. 16, the same components as those in FIG. 13 described above are denoted by the same reference signs, and detailed description thereof will be omitted.

In a pixel 9B, a trench (RDTI) 53 is formed as an in-pixel separation part. The trench 53 includes a metal film or an oxide film. The trench 53 is positioned at the center of the pixel 9B and is formed from the center of the pixel 9B toward a side 311 of an inter-pixel separation part 31.

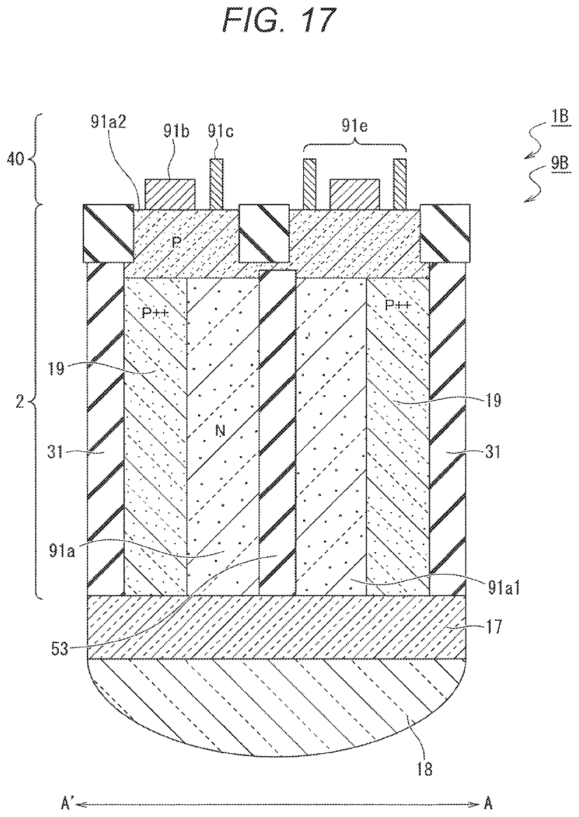

FIG. 17 illustrates a cross-sectional view of the pixel 9B taken, in a vertical direction, along the alternate long and short dash line A-A′ in FIG. 1. Note that, in FIG. 17, the same components as those in FIG. 3 described above are denoted by the same reference signs, and detailed description thereof will be omitted.

The trench 53 is formed from a back surface to a front surface side of a substrate 2 of the pixel 9B.

### Effects of Third Embodiment

As described above, according to the third embodiment, effects similar to those of the above-described first embodiment can be obtained, and even if same-color separation is performed by the trench 53, a decrease in the n-type semiconductor region 91a1 of the photodiode 91a can be reduced.

### First Modification of Third Embodiment

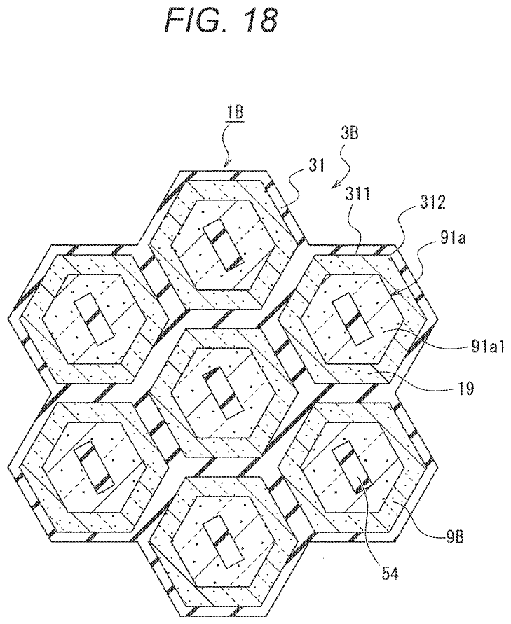

FIG. 18 is a plan view illustrating an example of pixels 9B arranged in a pixel array unit 3B in a first modification of the third embodiment. Note that, in FIG. 18, the same components as those in FIG. 16 described above are denoted by the same reference signs, and detailed description thereof will be omitted.

In the pixel 9B, a trench (RDTI) 54 is formed. The trench 54 includes a metal film or an oxide film. The trench 54 is positioned at the center of the pixel 9B and is formed from the center of the pixel 9B toward a corner part 312 of the inter-pixel separation part 31.

### Second Modification of Third Embodiment

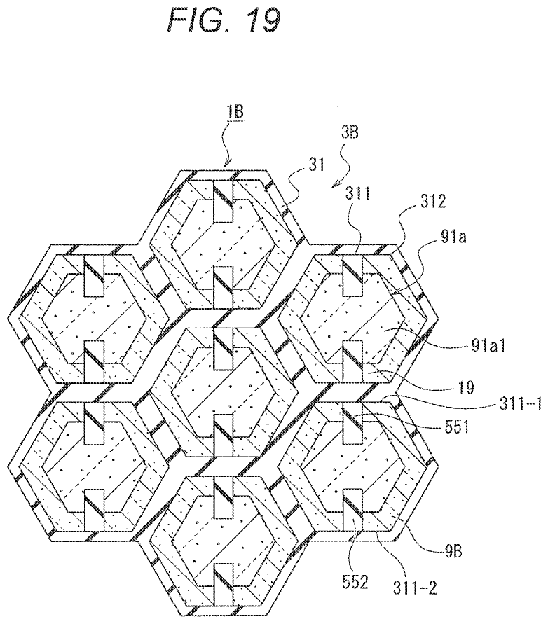

FIG. 19 is a plan view illustrating an example of pixels 9B arranged in a pixel array unit 3B in a second modification of the third embodiment. Note that, in FIG. 19, the same components as those in FIG. 16 described above are denoted by the same reference signs, and detailed description thereof will be omitted.

Trenches (RDTIs) 551 and 552 are formed in the pixel 9B. The trenches 551 and 552 include a metal film or an oxide film. The trench 551 is positioned on a side 311-1 of the inter-pixel separation part 31 of the pixel 9B, and is formed from the side 311-1 toward the center of the pixel 9B. The trench 552 is positioned on a side 311-2 of the inter-pixel separation part 31 of the pixel 9B, and is formed from the side 311-2 toward the center of the pixel 9B.

### Third Modification of Third Embodiment

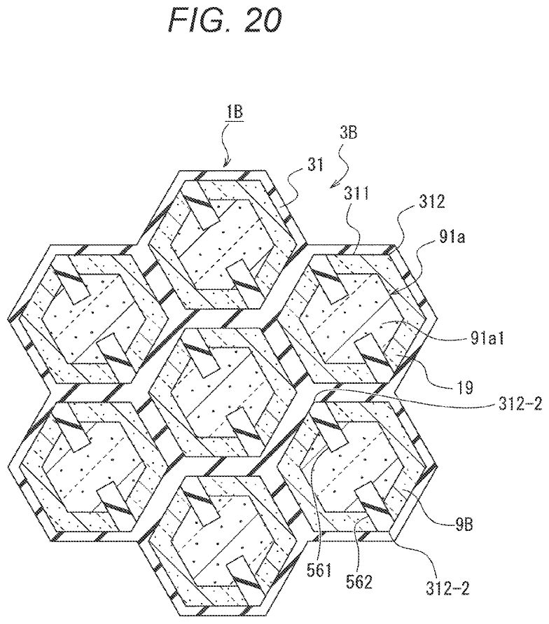

FIG. 20 is a plan view illustrating an example of pixels 9B arranged in a pixel array unit 3B in a third modification of the third embodiment. Note that, in FIG. 20, the same components as those in FIG. 16 described above are denoted by the same reference signs, and detailed description thereof will be omitted.

Trenches (RDTIs) 561 and 562 are formed in the pixel 9B. The trenches 561 and 562 include a metal film or an oxide film. The trench 561 is positioned at a corner part 312-1 of the inter-pixel separation part 31 of the pixel 9B, and is formed from the corner part 312-1 toward the center of the pixel 9B. The trench 562 is positioned at a corner part 312-2 of the inter-pixel separation part 31 of the pixel 9B, and is formed from the corner part 312-2 toward the center of the pixel 9B.

### Other Embodiments

As described above, the present technology has been described by the first to third embodiments, the modification of the first embodiment, the modification of the second embodiment, and the first to third modifications of the third embodiment, but it should not be understood that the description and drawings that constitute a part of the present disclosure limit the present technology. It will be apparent to those skilled in the art that various alternative embodiments, examples, and operation techniques may be included in the present technology when understanding the spirit of the technical content disclosed in the above-described first to third embodiments, the modification of the first embodiment, the modification of the second embodiment, and the first to third modifications of the third embodiment. Furthermore, the configurations disclosed in the first to third embodiments, the modification of the first embodiment, the modification of the second embodiment, and the first to third modifications of the third embodiment can be appropriately combined within a range in which no contradiction occurs. For example, configurations disclosed in a plurality of different embodiments may be combined, or configurations disclosed in a plurality of different modification examples of the same embodiment may be combined.

### <Example of Application to Electronic Apparatus>

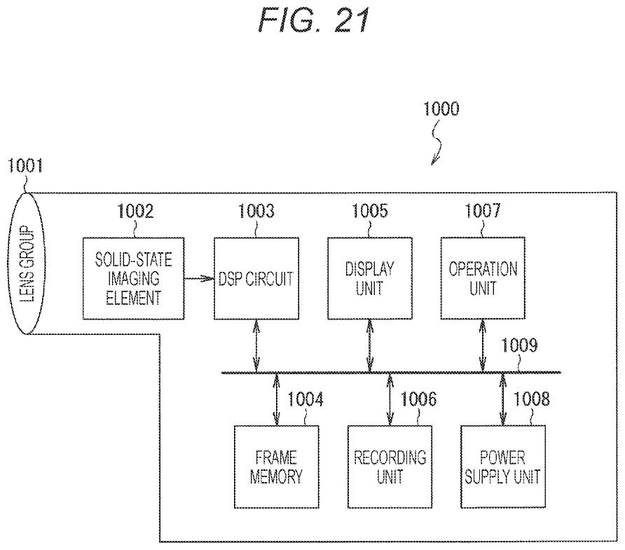

FIG. 21 is a block diagram illustrating a configuration example of an embodiment of an imaging device as an electronic apparatus to which the present technology is applied.

An imaging device 1000 in FIG. 21 is a video camera, a digital still camera and the like. The imaging device 1000 includes a lens group 1001, a solid-state imaging element 1002, a DSP circuit 1003, a frame memory 1004, a display unit 1005, a recording unit 1006, an operation unit 1007, and a power supply unit 1008. The DSP circuit 1003, the frame memory 1004, the display unit 1005, the recording unit 1006, the operation unit 1007, and the power supply unit 1008 are connected to one another via a bus line 1009.

The lens group 1001 captures incident light (image light) from a subject and forms an image on an imaging surface of the solid-state imaging element 1002. The solid-state imaging element 1002 includes the first to 14th embodiments of the solid-state imaging device described above. The solid-state imaging element 1002 converts an amount of incident light formed on an imaging surface by the lens group 1001, into an electrical signal on a pixel-by-pixel basis, and supplies the electrical signal as a pixel signal, to the DSP circuit 1003.

The DSP circuit 1003 performs predetermined image processing on the pixel signal supplied from the solid-state imaging element 1002, and supplies the image signal having been subjected to the image processing to the frame memory 1004 on a frame-by-frame basis, to temporarily store the image signal in the frame memory 1004.

The display unit 1005 includes, for example, a panel display device such as a liquid crystal panel or an organic electro luminescence (EL) panel, and displays an image in response to a pixel signal temporarily stored in the frame memory 1004 for each frame.

The recording unit 1006 includes a digital versatile disk (DVD), a flash memory, or the like, and reads and records a pixel signal temporarily stored in the frame memory 1004 for each frame.

The operation unit 1007 issues an operation command regarding various functions of the imaging device 1000 under operation by a user. The power supply unit 1008 supplies power to the DSP circuit 1003, the frame memory 1004, the display unit 1005, the recording unit 1006, and the operation unit 1007 as appropriate.

The electronic apparatus to which the present technology is applied is only required to be any apparatus that uses a photodetection device as an image capture unit (photoelectric conversion unit), and includes a mobile terminal device having an imaging function, a copying machine using a photodetection device as an image reading unit, and the like, in addition to the imaging device 1000.

Note that the present disclosure can also have the following configurations.

(1)

A light-receiving element including a pixel array unit in which a plurality of pixels is disposed in an array, the pixels being capable of generating an electrical signal according to light incident from outside,
in which each of the plurality of pixels includes
a photoelectric conversion region of a first conductivity type, the photoelectric conversion region photoelectrically converting the light incident,
an inter-pixel separation part that defines an outer edge shape of the pixels, and insulates and separates adjacent the pixels, and
a pinning region of a second conductivity type that is opposite to the first conductivity type, the pinning region being formed between the photoelectric conversion region and a sidewall of the inter-pixel separation part, and
the plurality of pixels is disposed in an array so as to form a honeycomb structure in which corner parts where a plurality of sides intersects are obtuse angles in plan view.

(2)

The light-receiving element according to (1),
in which the outer edge shape of the pixels is a regular hexagonal shape.

(3)

The light-receiving element according to (1),
in which each of the plurality of pixels has a dual pixel structure in which the photoelectric conversion region is separated into two by an in-pixel separation part.

(4)

The light-receiving element according to (3),
in which the in-pixel separation part is a first trench including a metal film or oxide film formed from a surface on a side opposite to an incident side of the pixel to the incident side.

(5)

The light-receiving element according to (4),
in which the first trench is positioned at the center of the pixel and is formed from the center of the pixel toward at least one corner part of the inter-pixel separation part.

(6)

The light-receiving element according to (4),
in which the first trench is positioned at the center of the pixel and is formed from the center of the pixel toward at least one side of the inter-pixel separation part.

(7)

The light-receiving element according to (3),
in which the in-pixel separation part is a second trench including a metal film or oxide film formed from a surface of an incident side of the pixel to a surface on a side opposite to the incident side.

(8)

The light-receiving element according to (7),
in which the second trench is positioned at the center of the pixel and is formed from the center of the pixel toward at least one corner part of the inter-pixel separation part.

(9)

The light-receiving element according to (7),
in which the second trench is positioned at the center of the pixel and is formed from the center of the pixel toward at least one side of the inter-pixel separation part.

(10)

The light-receiving element according to (7),
in which the second trench is positioned on at least one corner part of the inter-pixel separation part and is formed from the corner part of the inter-pixel separation part toward the center of the pixel.

(11)

The light-receiving element according to (7),
in which the second trench is positioned on at least one side of the inter-pixel separation part and is formed from the side of the inter-pixel separation part toward the center of the pixel.

(12)

The light-receiving element according to (1),
in which the pixel array unit further includes an on-chip lens formed for each of the pixels such that the light is condensed on the pixel.

(13)

An electronic apparatus including a light-receiving element including a pixel array unit in which a plurality of pixels is disposed in an array, the pixels being capable of generating an electrical signal according to light incident from outside,
in which each of the plurality of pixels includes
a photoelectric conversion region of a first conductivity type, the photoelectric conversion region photoelectrically converting the light incident,
an inter-pixel separation part that defines an outer edge shape of the pixels, and insulates and separates adjacent the pixels, and
a pinning region of a second conductivity type that is opposite to the first conductivity type, the pinning region being formed between the photoelectric conversion region and a sidewall of the inter-pixel separation part, and
the plurality of pixels is disposed in an array so as to form a honeycomb structure in which corner parts where a plurality of sides intersects are obtuse angles in plan view.

### REFERENCE SIGNS LIST

1, 1A, 1B Solid-state imaging device
2 Substrate
3, 3A, 3B Pixel array unit
4 Vertical drive circuit
5 Column signal processing circuit
6 Horizontal drive circuit
7 Output circuit
8 Control circuit
9, 9A, 9B, B9 Pixel
10 Pixel drive wiring line
11 Vertical signal line
12 Horizontal signal line
17 Color filter
18 On-chip lens
19 Pinning region
21a, 21b Gate electrode
22 Contact
31 Inter-pixel separation part
40 Wiring layer
51, 52, 53, 54, 551, 552, 561, 562 Trench
91a Photodiode
91a1 n-type semiconductor region
91a2 p-type semiconductor region
91b Transfer transistor
91c floating diffusion (FD) unit
91d Conversion-efficiency adjustment transistor
91e Amplification transistor
91f Selection transistor
91g Reset transistor
311, 311-1, 311-2 Side
312, 312-1, 312-2 Corner part
1000 Imaging device
1001 Lens group
1002 Solid-state imaging element
1003 DSP circuit
1004 Frame memory
1005 Display unit
1006 Recording unit
1007 Operation unit
1008 Power supply unit
1009 Bus line

1. A light-receiving element comprising a pixel array unit in which a plurality of pixels is disposed in an array, the pixels being capable of generating an electrical signal according to light incident from outside,
wherein each of the plurality of pixels includes
a photoelectric conversion region of a first conductivity type, the photoelectric conversion region photoelectrically converting the light incident,
an inter-pixel separation part that defines an outer edge shape of the pixels, and insulates and separates adjacent the pixels, and
a pinning region of a second conductivity type that is opposite to the first conductivity type, the pinning region being formed between the photoelectric conversion region and a sidewall of the inter-pixel separation part, and
the plurality of pixels is disposed in an array so as to form a honeycomb structure in which corner parts where a plurality of sides intersects are obtuse angles in plan view.

2. The light-receiving element according to claim 1,
wherein the outer edge shape of the pixels is a regular hexagonal shape.

3. The light-receiving element according to claim 1,
wherein each of the plurality of pixels has a dual pixel structure in which the photoelectric conversion region is separated into two by an in-pixel separation part.

4. The light-receiving element according to claim 3,
wherein the in-pixel separation part is a first trench including a metal film or oxide film formed from a surface on a side opposite to an incident side of the pixel to the incident side.

5. The light-receiving element according to claim 4,
wherein the first trench is positioned at a center of the pixel and is formed from the center of the pixel toward at least one corner part of the inter-pixel separation part.

6. The light-receiving element according to claim 4,
wherein the first trench is positioned at a center of the pixel and is formed from the center of the pixel toward at least one side of the inter-pixel separation part.

7. The light-receiving element according to claim 3,
wherein the in-pixel separation part is a second trench including a metal film or oxide film formed from a surface of an incident side of the pixel to a surface on a side opposite to the incident side.

8. The light-receiving element according to claim 7,
wherein the second trench is positioned at a center of the pixel and is formed from the center of the pixel toward at least one corner part of the inter-pixel separation part.

9. The light-receiving element according to claim 7,
wherein the second trench is positioned at a center of the pixel and is formed from the center of the pixel toward at least one side of the inter-pixel separation part.

10. The light-receiving element according to claim 7,
wherein the second trench is positioned on at least one corner part of the inter-pixel separation part and is formed from the corner part of the inter-pixel separation part toward a center of the pixel.

11. The light-receiving element according to claim 7,
wherein the second trench is positioned on at least one side of the inter-pixel separation part and is formed from the side of the inter-pixel separation part toward a center of the pixel.

12. The light-receiving element according to claim 1,
wherein the pixel array unit further includes an on-chip lens formed for each of the pixels such that the light is condensed on the pixel.

13. An electronic apparatus comprising a light-receiving element including a pixel array unit in which a plurality of pixels is disposed in an array, the pixels being capable of generating an electrical signal according to light incident from outside,
wherein each of the plurality of pixels includes
a photoelectric conversion region of a first conductivity type, the photoelectric conversion region photoelectrically converting the light incident,
an inter-pixel separation part that defines an outer edge shape of the pixels, and insulates and separates adjacent the pixels, and
a pinning region of a second conductivity type that is opposite to the first conductivity type, the pinning region being formed between the photoelectric conversion region and a sidewall of the inter-pixel separation part, and
the plurality of pixels is disposed in an array so as to form a honeycomb structure in which corner parts where a plurality of sides intersects are obtuse angles in plan view.
